(19) United States
(12) Patent Application Publication
(10) Pub. No.: US 2014/0176336 A1
(43) Pub. Date: Jun. 26, 2014

(54) SYSTEM, METHOD, AND APPARATUS FOR REMOTELY MONITORING SURGE ARRESTER CONDITIONS

(71) Applicant: eLuminon, LLC., West Linn, OR (US)

(72) Inventors: Ding Li, West Linn, OR (US); Jicheng Lu, Suzhou (CN)

(73) Assignee: eLuminon, LLC., West Linn, OR (US)

(21) Appl. No.: 14/104,196

(22) Filed: Dec. 12, 2013

Related U.S. Application Data
(60) Provisional application No. 61/740,798, filed on Dec. 21, 2012.

(51) Int. Cl. G01R 1/38

(52) U.S. Cl. CPC G01R 1/38
USPC 340/870.01

(57) ABSTRACT

A system and method for real-time remotely (i.e., at least several miles away) monitoring MOV surge arresters conditions is provided along with a method and circuitry for sensing the total leakage current of a surge arrester in a power grid. Leakage current circuitry may include a MOV arrester leakage current sensing block having shunt circuitry formed using a biasing resistor, one or more opto-couplers that isolate the radio module system from the MOV arrester stem line and monitors the total leakage current and other states of the primary stage, and a mini ZOV that acts as a surge protection device. The outputs of the opto-couplers can be set up to provide a linear or digital output or both to a communications network. The communications network can transmit a signal corresponding to a fault state of a surge arrester to a remote central control center. An alternative and complementary way of monitoring MOV condition is also provided by registering the time and counts of the lightning strikes with a renovated mechanical counter telemetry.

### PRIORITY CLAIM

This application is a non-provisional of, and claims priority from, U.S. Provisional Patent Application Ser. No. 61/740,798, filed Dec. 21, 2012, the contents of which are hereby incorporated herein in their entirety.

### BACKGROUND OF THE INVENTION

1. Field of the Invention

The present inventive concepts relate to systems, methods, and apparatuses for monitoring metal-oxide varistor (MOV) arrester conditions in a national power grid, and more particularly to systems, methods, and apparatuses for remotely monitoring such conditions using power line communication (PLC) networks, wireless mesh networks, and/or cellular GSM/GPRS or CDMA network systems, individually or in hybrid combination. The present inventive concepts further relate to an innovative method and apparatus for acquiring the total leakage current for signal transmitting, as well as an innovative mechanical counter telemetry apparatus and method for remote readout in either an analog or a digital signal transmission mode, which may be implemented using existing off-the-shelf mechanical surge counter products.

2. Related Art

A metal-oxide varistor (MOV) is a nonlinear current/voltage conductance device that acts like an insulator at regular line voltage while acting like a conductor at high voltage/current surges. A MOV arrester is an indispensable device for arresting surges in modern electrical power transmission lines. Normally it is a very reliable device. However, after long usage in a hostile environment (e.g., having frequent voltage/current surges and/or lightning strikes), it may deteriorate and can become degraded, leading to eventual failure. It is therefore common practice to install some kind of arrester monitors at particularly significant points in a power grid, such as at high/super high voltage transmission lines, transformers substations, underground to aboveground power line transition points, switch cabinets as an entry to local facilities, and heavy inductance machine transformers.

As the arrester becomes degraded, its resistive component of leakage current starts increasing dramatically compared to its capacitive component. Although the leakage current normally ranges between a few hundreds of μAs, once degraded, it can increase up to a few mAs, eventually leading to a thermal runaway. Based on this characteristic, a variety of arrester monitors have been designed and put into usage to detect excess leakage current. Among them are drop-out high-voltage fuses and mechanical surge counters combined with a coil driven mA meter. The latter is particularly popular, and advanced versions can register the occurrence of an arresting process above a specific, predetermined amplitude and display a warning signal.

One advantage of these devices is that there is no need for an external power supply and thus it is easy to use and cost effective. Unfortunately, however, the disadvantages are that they do not provide a real-time monitoring device and cannot monitor or transmit a report of the arrester events remotely. Maintenance teams have to routinely deploy crews for maintaining and repairing these devices. Once an event which may cause a possible problem occurs, the maintenance teams have to physically travel along the power line to locate any bad nodes. This can be very time consuming and costly.

Various related art focuses on registering the surge current impulses, measuring and displaying the leakage currents, and providing audible warning signals. U.S. Pat. Nos. 6,879,479 and 7,336,193, for instance, disclose various devices for detecting and indicating arrester conditions, but fail to provide an adequate solution to the problems faced by the industry. Some difficulties associated with realizing a real-time and remote monitoring apparatus may include a lack of sufficient remote communication protocols as well as the lack of a reliable and cost-effective field power source.

What is desired, therefore, is a cost-effective and reliable system, method, and apparatus for detecting and remotely reporting arrester events. The industry would also be benefited by an innovative mechanical counter telemetry apparatus and method for providing a remote readout in either an analog or a digital signal transmission mode, which may be implemented using existing off-the-shelf mechanical surge counter products.

### SUMMARY OF THE INVENTION

According to various principles of the present inventive concepts, a power grid surge arrestor monitoring system is provided that can remotely monitor surge arrester conditions and transmit information related thereto in real-time using various network communication technologies. In particular, a system and method is provided that can acquire the total leakage current of the surge arrester using opto-couplers configured to monitor the leakage current in real-time. The system can receive and transmit a signal corresponding to the leakage current through a sensor and ADC or by triggering the GPIO pins of a RF RX/1X modem of a mesh network module or a cellular GPRS/CDMA module or a PLC module. The appropriate signals can then be sent to a control center through a mesh network or a cellular GPRS/CDMA network, which may be implemented independently or in hybrid combination.

According to additional aspects of the inventive concepts, a network system can monitor and register the surge strikes, and remotely and timely report the events to a control center through a communication network. This method and apparatus can, for instance, implement an improvement to existing mechanical driven surge counters.

The various detection and transmission apparatuses may be implemented in separate cases or enclosures or may be integrated into a single enclosure. These solutions may further make use of the same set of communication resources for signal transmission. Accordingly, the principles of the present inventive concepts can provide a solution to industry problems by providing a leakage current monitor that offers convenience by remotely tracking degradation history of the surge arresters in use.

In a system that utilizes a mesh network, the mesh network can, for instance, be established based on a ZigBee compliant wireless platform (or any other individual RF protocol, such as SNAP) which can automatically broadcast through a mesh route or a predefined route. If conditions allow, however, a power line communication (PLC) protocol can be implemented using existing power line infrastructures in addition to, or instead of the mesh network. The benefits of using a mesh network are low power requirements and no need for cellular service coverage. However, to effectively implement such a system, all of the mesh network nodes should be within the mesh network radio range.

One major blockage that may have impeded the industry's implementation of a remote monitoring system is the unavailability of a realistic and reliable power supply source. Various embodiments of the present inventive concepts also provide solutions to the industry's power supply problems. These possible solutions include, for instance, solar panels, wind turbines, CVTs, SSRs, surging strike charging using an induction coil such as a Rogowski coil, and the electromotive force induced in the 60 Hz high voltage power lines by the EMI field.

According to one embodiment of the inventive concepts, an innovative apparatus and method for sensing and monitoring the leakage current of a surge arrester is provided using opto-coupler configurations. Advantages of this apparatus and method include its simplicity, its reliability, and its cost-effectiveness. In this embodiment, a bi-directional opto-coupler is implemented for its higher (almost double) conversion efficiency than a single directional one. In addition, this solution can also provide isolation of the radio module, which may be vulnerable to voltage or current surges, from the arrester circuit through which the surge is intentionally directed. Both linear and digital output modes could be used depending on the purpose. Such purposes may include, for instance, measuring the leakage current in real-time, or triggering the radio transceiver and microprocessor module's inputs to wirelessly send out messages over a relatively large distance once the current exceeds the predetermined threshold.

A Router Node and Sleeper Node configuration can be provided in a mesh network in order to reduce power consumption of the node devices in the system and thereby reduce costs. However, a synchronicity timing system may alternatively be implemented, in which case, separate Router and Sleeper Nodes would not be necessary. Rather, in a synchronicity timing system, all the nodes could be set up to wake up at the same time for a short period of time (e.g., at 12:00 am for a one minute period), check the fault status, and go back to sleep if no problems are detected.

A hierarchy network system can be established for more broad data access by connecting the database center to other types of wideband internet systems through a device , such as a SNAP connect E10, for example, to communicate with a PC or other communication device such as a smart phone or Wi-Fi connected tablet or other hand-held device. The E10 provides a fast, seamless connection between any SNAP network to any other network running TCP/IP and other standard protocols. According to another embodiment of the inventive concepts, its function can be effectively realized by a serial connection such as RS232 between a SNAP network module and a GSM/GPRS network module, which has proven to be a more simple and cost effective way for implementation.

As an alternative, or in addition to, the wireless mesh network system, the reporting tasks performed by the wireless mesh network can be accomplished using cellular GSM/GPRS or CDMA modules through a public communication network in a so-called point-to-point (P2P) or machine-to-machine (M2M) mode. The cellular GSM/GPRS or CDMA system is especially suitable for a remote, sparse population or a mountain area where the substation density is much less than the urban area, and where the distance between power transmission towers much larger. The primary advantage of cellular network systems is its much larger transmission range as compared to mesh network systems.

A third possible setup is a hybrid network topology where a wireless mesh network is connected with a cellular GSM/GPRS or CDMA module in a serial interface for signal transmission using AT commands. When the Router Nodes are configured to carry as many Sleep Nodes as possible in the hybrid network, this topology can save significant cost of service fees that the GPRS network nodes may otherwise accumulate and be required to be paid to the mobile carrier for the data transmission.

Mechanical Counters have been used in the field to record the number of lightning strikes with proven reliability. Advantages of the mechanical counter are that it does not require a power supply to operate, and the recorded data is not as easily corrupted as in an electronic system. The primary disadvantage, however, is that it requires manual operation to read the recorded counts and to reset the counter, which requires a technician to be physically present at the unit.

According to another aspect of the present inventive concepts, the conventional mechanical counter can be renovated to allow the recorded counts of the mechanical counter to be read electronically and remotely. This design enhancement benefits from the proven reliability of existing mechanical counter designs, while allowing technicians offsite to read the recorded count.

In a summary, according to principles of the inventive concepts, a system, method, and apparatus for remotely monitoring surge arrester conditions provides a solution to industry problems that no longer requires deployment of servicemen for routine cruise checks and on-field searching for fault locations once a triggering event occurs. The present inventive concepts can therefore help prevent severe power line accidents from occurring, and can further greatly reduce the costs of operating the power grid.

Various aspects, embodiments, and configurations of the inventive concepts are possible without departing from the principles disclosed herein. The inventive concepts are therefore not limited to any of the particular aspects, embodiments, or configurations described herein.

### BRIEF DESCRIPTION OF DRAWINGS

The foregoing and additional objects, features, and advantages will become more readily apparent from the following detailed description of preferred embodiments, taken in conjunction with the accompanying drawings, in which:

FIG. 1 is a schematic diagram illustrating a leakage current detector unit, an RF RX/TX CMU module, and a solar panel power supply system arranged at one of the arrester circuits, according to one embodiment incorporating principles of the present inventive concepts;

FIG. 2 is a schematic diagram of a monitoring node showing three arresters, each connected to one phase of a three-phase high voltage power line, and further showing monitoring units and a transmitting unit constructed according to principles of the present inventive concepts;

FIG. 3 is a schematic diagram illustrating a capacitive voltage transformer (CVT) that can be used as an external power supply source according to additional principles of the present inventive concepts;

FIGS. 4A-4B are schematic diagrams of various potential internal power sources constructed according to still additional principles of the present inventive concepts;

FIGS. 5A-5C are schematic illustrations of a device for converting electromagnetic induction (EMI) induced electromotive force (EMF) into an external power supply according to a still further principles of the present inventive concepts;

FIGS. 6A-6B are schematic diagrams illustrating a system for monitoring arresters using a mesh network only topology and hierarchy, according to still further principles of the present inventive concepts;

FIG. 7 is a schematic diagram illustrating a system for monitoring arresters using a cellular GSM/GPRS or CDMA network only topology, according to still further principles of the present inventive concepts;

FIG. 8 is a schematic diagram illustrating a hybrid network topology, according to still further principles of the present inventive concepts;

FIGS. 9A-9C are schematic diagrams respectively illustrating a conventional mechanical counter dial, a mechanical counter dial that has been modified to provide an electronic signal output corresponding to the position of the mechanical counter dial, and a telemetry system comprising a mechanical counter that has been modified to provide a remote electronic readout, according to still further principles of the present inventive concepts;

FIG. 10 is a schematic diagram illustrating a mechanical counter modified to produce an analog signal output corresponding to the counter position, according to still further principles of the present inventive concepts;

FIG. 11A is a somewhat schematic diagram of a mechanical counter modified to produce a digital readout corresponding to a counter position relative to encoded positions on a stationary drum, according to still further principles of the present inventive concepts; and

FIG. 11B is a schematic diagram illustrating the various encoded positions of the stationary drum.

### DETAILED DESCRIPTION

Various configurations incorporating principles of the present inventive concepts in illustrative embodiments will now be described with reference to the accompanying drawings. Additional features, benefits and configurations will be readily apparent to those of ordinary skill in the art based on this disclosure and all such variations are considered within the scope of the present invention.

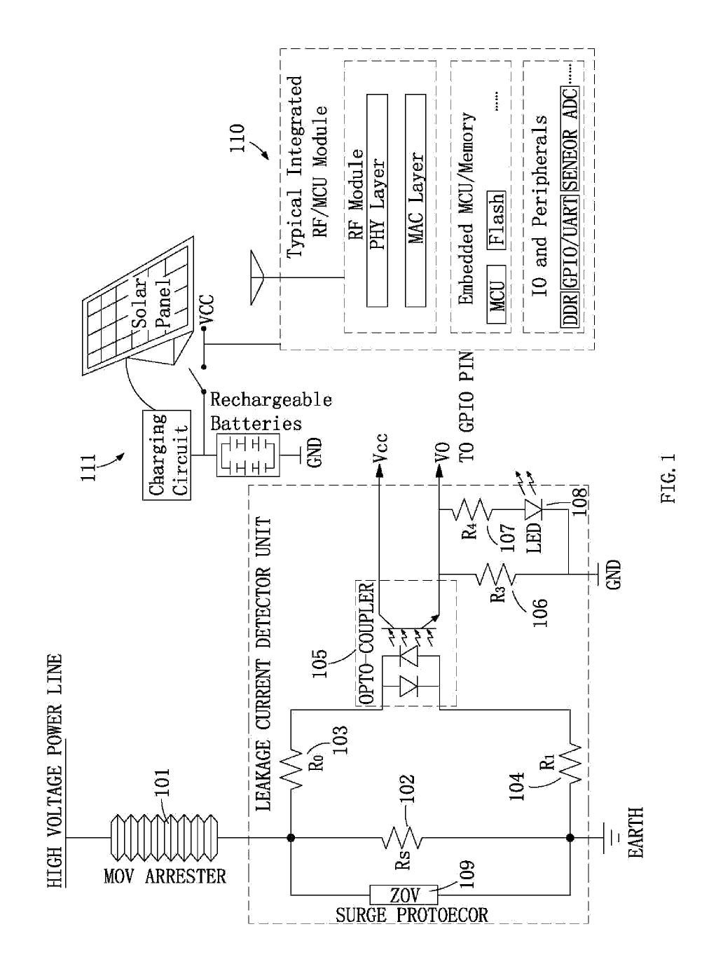

FIG. 1 is a schematic diagram of the leakage current detector unit (LCDU) combined with a radio (e.g., RF RX/TX CMU) module and the solar panel power supply system at one of the arrester circuits. Referring to FIG. 1, a system and its circuitry is illustrated for sensing the total leakage current of a surge arrester to acquire signal thereof The system can include a MOV arrester leakage current sensing block which includes shunt circuitry comprising a biasing resistor 102 and one or more opto-couplers (i.e., opto-coupler configurations) 105. The circuitry is preferably configured to isolate a radio module system from the MOV arrester stem line to reduce the radio module system's vulnerability to high voltage or high current surges, such as lightning strikes, in the MOV arrester. The opto-coupler circuitry preferably monitors the total leakage current and other states of the primary stage. A mini ZOV (zinc-oxide varistor) 109 can also be provided to serve as a surge protection device for the leakage current detector unit.

The radio module can include, for instance, an RF transceiver with baseband modem, a hardwired MAC and an embedded microcontroller with internal flash memory. In a preferred embodiment, an audible and/or visible event alarm can also be set up at the network terminal nodes to provide an audible and/or visual notification of a fault status.

Outputs of the opto-couplers can be set up in linear or digital mode, or both. The linear mode output can be connected to a sensor ADC input of a radio module to monitor the analog signal of the leakage current in real time. Alternatively, or additionally, a digital mode configuration can be configured to send a logic (on/off) signal output configured to trigger GPIO pins of an RF transceiver module when the leakage current exceeds a pre-determined threshold, thereby indicating an initial deteriorating condition of the arrester. This, in turn, can wake up the interrupt GPIO pins and transmit the state change through the communications network.

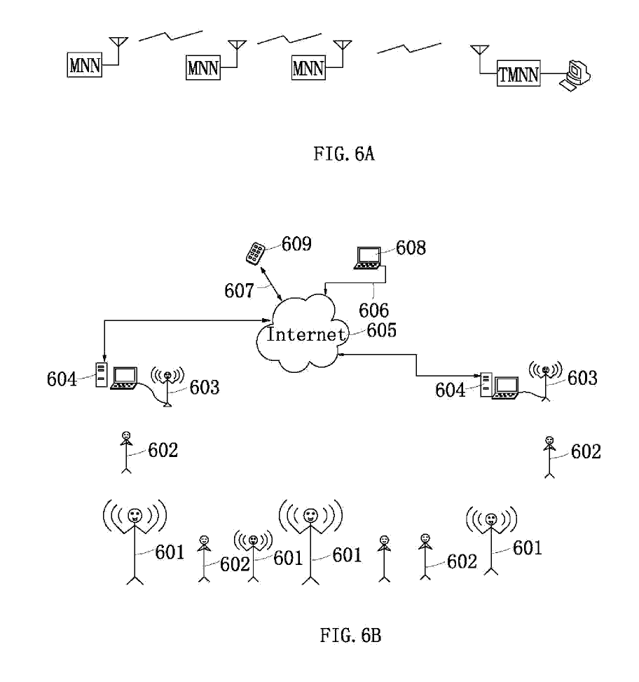

For instance, the state change can be transmitted to remote peers of a mesh network system and through the mesh network to a central control center and upper levels of the network hierarchy. As will be described in further detail with reference to FIGS. 6A and 6B, the wireless mesh network can, for instance, be provided using ZigBee, an IEEE 802.15.4 compliant solution, or any other individual RF protocols, such as SNAP. Alternatively, or in addition, the communications system can include cellular communications systems and protocols or power line communication (PLC) systems and protocols.

Various power systems can be implemented to provide power to the monitoring systems. For instance, systems installed in substations and in the field can, for example, be powered by mini solar panels (or other adequate power sources) 111, and those installed in the switch cabinets nearby low voltage main lines can make use of these line voltage power supplies. An internal battery level and in-case temperature monitor can also be embedded in the radio module, and data corresponding to the battery level and temperature can be collected through the sensor ADC and transmitted together with the arrester condition signals.

A first embodiment of a monitoring system for monitoring and reporting a MOV arrester condition will now be described in more detail with reference to FIG. 1. As shown in FIG. 1, a MOV arrester 101 connects to a high voltage power line at a first terminal and connects to the Leakage Current Detector Unit (LCDU) at a second terminal. The MOV arrester 101 is further connected to the earth ground through the LCDU. Directly connected to the second arrester terminal are the sensing/biasing resistor Rs 102, a current limiting resistor RO 103, and a surge protection device ZOV 109. The primary terminals of an opto-coupler 105 connect to the first current limiting resistor RO 103 and another current limiting resistor R1 104. The secondary terminals of the opto-coupler connect to Vcc and an output resistor R3 106, voltage divider resistor R4 107 and LED indicator 108, as well as to the GPIO pin of the RF module 110.

The resistance of the sensing/biasing resistor Rs 102 can be selected to determine the leakage current threshold. The resistance of the output resistor R3 106 should be selected to ensure that a photo-sensing transistor is operating in a saturation mode, and that the output voltage is sufficient to trigger the GPIOs corresponding to the pre-determined leakage current threshold.

The right-hand portion of FIG. 1 provides a schematic diagram of a conventional radio module comprising an RF Transceiver/MCU chip. The RF Transceiver/MCU chip can include a PHY layer, MAC layer, Clock section, MCU and Memory section, and peripherals. The radio module normally supports SPI, UART, Timers, Temp Sensor, Battery Level Monitor, and Sensor ADC channels.

A low power solar panel system 111 is also shown here as providing the power source, combined with a charge controller, rechargeable battery, and regulating circuits, for the power module. Other types of power supplies are also contemplated, however, and various alternative embodiments are shown in FIGS. 3-5C.

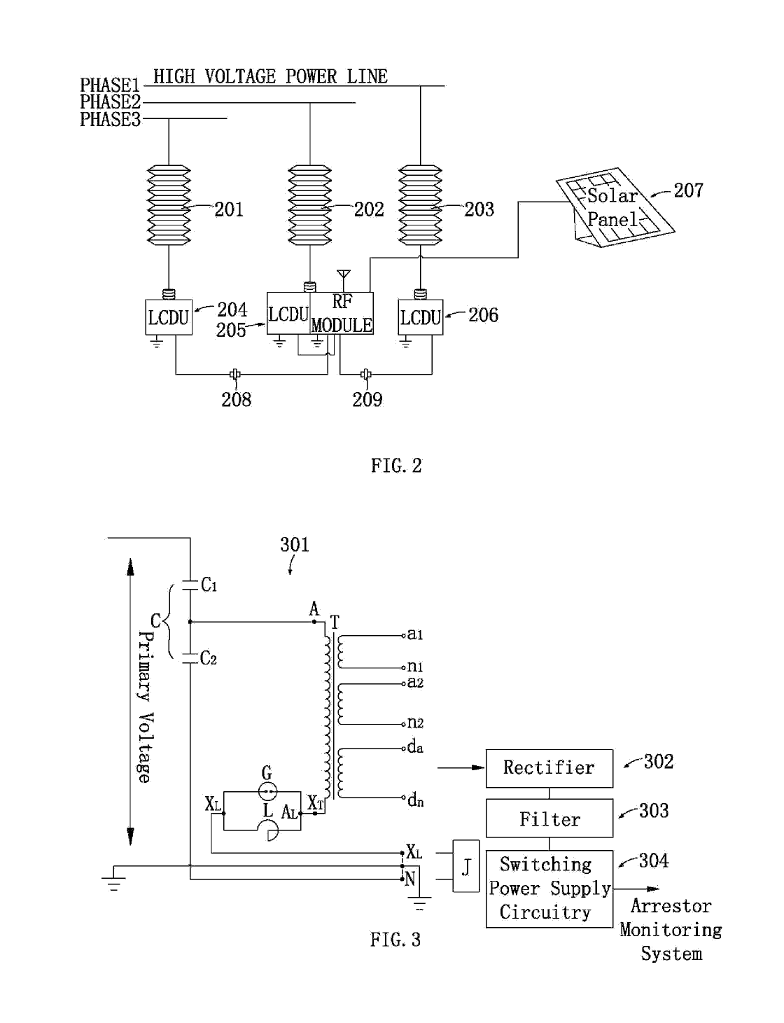

FIG. 2 is an installation diagram illustrating connection of a monitoring system at a monitoring node to a three-phase power line. Referring to FIG. 2, at one of the monitoring nodes, three arresters 201-203 are each connected to a respective phase of a high-voltage power line. Each monitoring node (e.g., a Router or Sleeper Node) can have three monitoring units 204-206 installed, corresponding to each phase of a 3-phase power line. One of the monitoring units 205, normally in the center but not limited thereto, comprises a housing that encloses a leakage current detector unit (LCDU), an RF module, a voltage regulating unit, charge controller, and re-chargeable batteries connected to an external power supply (which may be a low power solar panel 207). The housing for the other two monitoring units 204, 206, however, only enclose a LCDU which may connect to the central unit 205 through signal/power cable wires and waterproof connectors 208, 209.

FIGS. 3-5C are schematic diagrams illustrating alternative types of power supplies, which will now be described in further detail with reference to these figures. Referring first to FIG. 3, a capacitive voltage transformer (CVT) 301 may have an unregulated 100-200 volt AC output that can be used as an external power supply source in conjunction with a rectifier 302, filter 303, and a voltage regulator circuitry 304. The availability of the CVT terminal output for use in this application may depend on authorization by the utilities and power grid regulations. As used in FIG. 3, the labels represent the following:

C—carrier coupling capacitance

c₁—high voltage capacitance

c₂—medium voltage capacitance

N—carrier communication terminal

J—combined filter (self-prepared by the users)

G—protective device

L—compensation reactor

T—medium voltage transformer

A—high voltage terminal of medium voltage transformer

X_{T}—low voltage terminal of medium voltage transformer

A_{L}—high voltage terminal of compensation reactor

X_{L}—low voltage terminal of compensation reactor

Z—damping device

a₁-n₁—main secondary No. 1 winding terminal

a₂-n₂—main secondary No. 2 winding terminal

dₐ-dₐ—residual voltage winding terminal

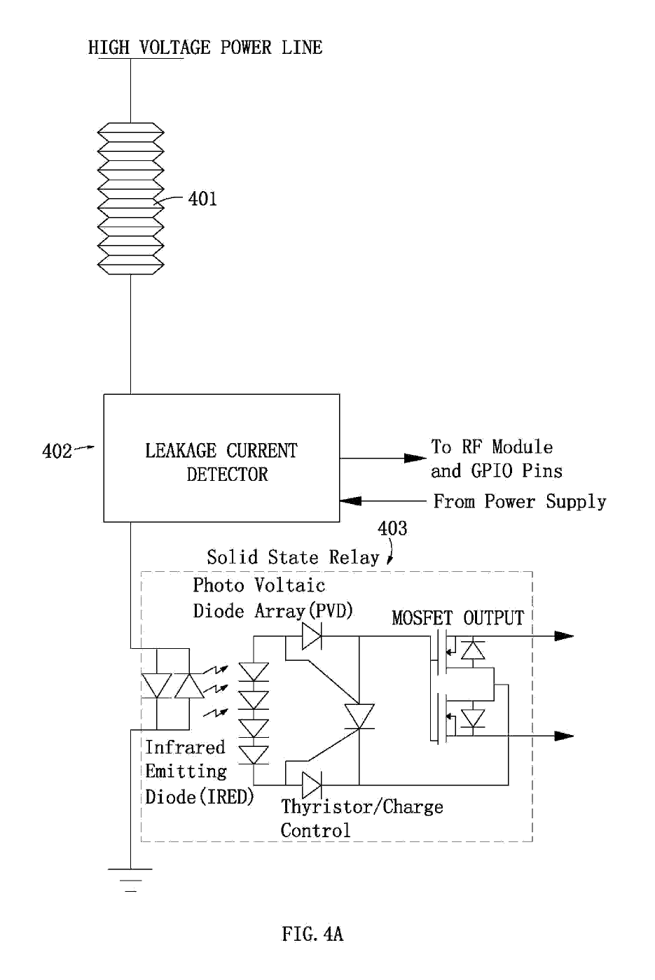

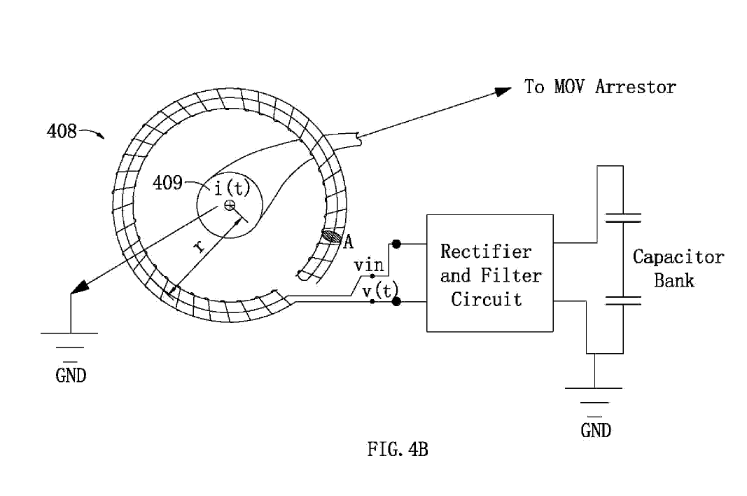

Referring now to FIG. 4A, an internally available power source may be provided using a solid-state relay (SSR) 403 inserted in the ground line of the arrester 401. The SSR provides an energy conversion device when the power consumption level of the said arrester monitoring system is less than the pre-determined leakage current threshold level. If the power consumed by the monitoring and transmission device is small enough, the power generated by the SSR could be used to power the equipment without the need for an external power source.

Referring to FIG. 4B, an alternative way of generating power internally makes use of striking energy, such as a lightning strike current, flowing through the MOV to the earth ground. In this embodiment, power is collected from the striking energy using an induction coil such as a Rogowski coil 408 that can be configured to surround the wire 409 in the MOV earth ground terminal. The collected energy can be stored in some kind of energy storage device, such as a capacitor bank. Before storing the collected power, the striking energy can be processed through a rectifier and filter circuitry, and the LCDU and radio module systems can be powered up with some delay, to detect the leakage current, convert to digital output or trigger the GPIO pins, count the strike or strikes, register the time, and send the data out for remote readout.

An estimate of the energy level available through this type of system suggests it could be sufficient to provide the desired power requirements. Assuming a typical lightning strike has a 10 kA peak current with a 20 us pulse width and a residual voltage of about 200V, this would be sufficient to generate a transient power of 40 W, which is large enough to power up a sensing and radio module system long enough to perform the desired operations.

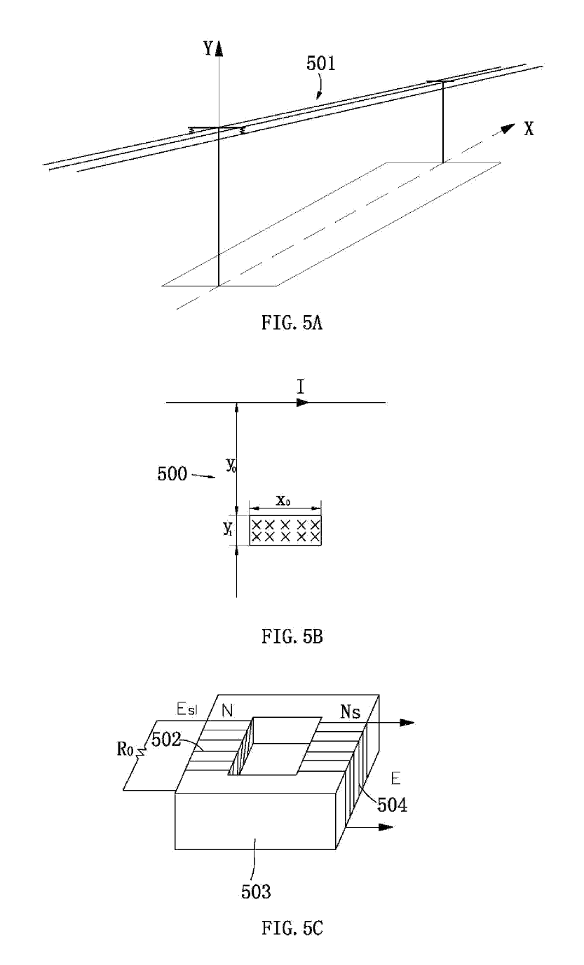

FIGS. 5A-5C are schematic illustrations of an EMI induction system 500 configured to use an electromagnetic induction (EMI) induced electromotive force (EMF) through a high-voltage power line 501 as an external power supply. Referring to FIGS. 5A-5C, a toroidal coil 502 with a ferromagnetic core 503 can be placed at a desired distance underneath or nearby the high voltage power lines 501 with a direction arranged perpendicular to the current flow in the said power lines 501 in order to maximize the magnetic flux induced by the alternative current flow and minimize the flux cancelling by the other phase of power lines. The induced current in the coil 502 will induce a self-inductance electromotive force (EMF) that will further induce the secondary coil 504 in the same core to generate a mutual-inductance electromotive force (EMF) that can be used as a power supply for the monitoring system. The equations derived below and the estimated results show that it is likely possible to provide a sufficient power source for the monitoring system if the EMI apparatus is carefully designed and implemented.

Assume the high voltage transmission line 501 carries an AC current in a form as follows:

I=I₀ sin ωt (1)

The flux of the magnetic field generated in the N turns of winding in the primary coil 502 as shown in FIG. 5B by the AC current is represented by the equation:

$$Φ = \int \int \vec{B} \cdot {d s}^{} = \frac{{μ}_{0}}{4 π} {\int }_{0}^{{y}_{1}} \frac{2 I}{{y}_{0} + y} {x}_{0} d y = \frac{{μ}_{0}}{4 π} \cdot 2 I {x}_{0} ln \frac{{y}_{0} + {y}_{1}}{{y}_{0}} = \frac{{μ}_{0}}{4 π} \cdot 2 {I}_{0} {x}_{0} ln \frac{{y}_{0} + {y}_{1}}{{y}_{0}} sin ω t \qquad ( 2 )$$

The EMF generated in the N turns of coil will be represented by the following equation:

$${ɛ}_{em} = - N \frac{d Φ}{d t} = - N \cdot \frac{{μ}_{0}}{4 π} \cdot {x}_{0} ln \frac{{y}_{0} + {y}_{1}}{{y}_{0}} \cdot {I}_{0} ω cos ω t \qquad ( 3 )$$

The current induced in the primary coil 502 is calculated as follows:

$${i}_{em} = \frac{{ɛ}_{em}}{{R}_{0}} = - N \cdot \frac{{μ}_{0}}{4 π} \cdot {x}_{0} ln \frac{{y}_{0} + {y}_{1}}{{y}_{0}} \cdot \frac{{I}_{0}}{{R}_{0}} ω cos ω t \qquad ( 4 )$$

The self-induced EMF in the primary coil 502 is calculated using the following equation:

$${ɛ}_{si} = - L \frac{d {i}_{em}}{d t} = μ {N}^{2} V \cdot N \frac{{μ}_{0}}{4 π} {x}_{0} ln \frac{{y}_{0} + {y}_{1}}{{y}_{0}} \cdot \frac{{I}_{0}}{{R}_{0}} {ω}^{2} sin ω t \qquad ( 5 )$$

where L is the inductance of the coil, V is the volume of the coil, and μ=μ₀μᵣ is the magnetic permeability of the magnetic medium in the coil. The total EMF in the primary coil 502 will be determined by the equation:

εₜₒₜ=εₑₘ+εₛᵢ (6)

The EMF of the secondary coil 504 will be determined by this equation:

$$ɛ = \frac{{N}_{s}}{N} {ɛ}_{tot} \qquad ( 7 )$$

Accordingly, assuming μᵣ=10000 in a typical transformer core 503 made of high relative permeability silicon steel sheet, and further assuming: N=1000, V=0.1×0.1×0.3 m³,y₀=3 m, y₁=0.1 m, I₀=400A, R₀=10ω, Ω=2πf=6.28×60. By inserting these values into equations (5) and (3), we got the amplitude of EMF of the primary coil as 5.6V.

εₜₒₜ=εₑₘ+εhd si≈5.6V

By properly selecting the number of turns Nₛ of the secondary coil 504, the desired output voltage can therefore be obtained.

FIG. 6A is a schematic diagram illustrating a mesh network only topology, where the label MNN means a mesh network node. Through each of the mesh network nodes, the system can relay the signal all the way to the terminal node (labeled as TMNN), which can be connected to a database server (such as a PC or other computing device, for example) in a control center.

FIG. 6B is a schematic diagram illustrating additional details of a mesh network hierarchy and a hybrid communications network in an arrester monitoring system according to principles of the present inventive concepts. Referring to FIG. 6B, a mesh network can comprise Routers (or Router Nodes) 601, Sleepers (or Sleeper Nodes) 602, Terminal Nodes 603, a Database Server at a control center 604, and internet connections 605. An Ethernet 606 or 3G/4G 607 infrastructures can also be used, for instance, to access the internet and extend the range of the data communication capabilities for access such as by any PC 608 or smart phone 609, or other network connected computing device.

As illustrated in FIGS. 6A-6B, a wireless mesh networking system can be provided for real-time remote (several miles away) monitoring of MOV surge arrester conditions. Such a system can include a plurality of nodes, including both Router 601 and Sleeper Nodes 602. The Router Nodes 601 are preferably always powered on and active, while the Sleeper Nodes 602 can be configured to enter a low power state and remain inactive until awoken based on a predetermined condition. In this way, the Sleeper Nodes 602 can consume significantly less power and may be operated for years, for instance, on conventional disposable batteries.

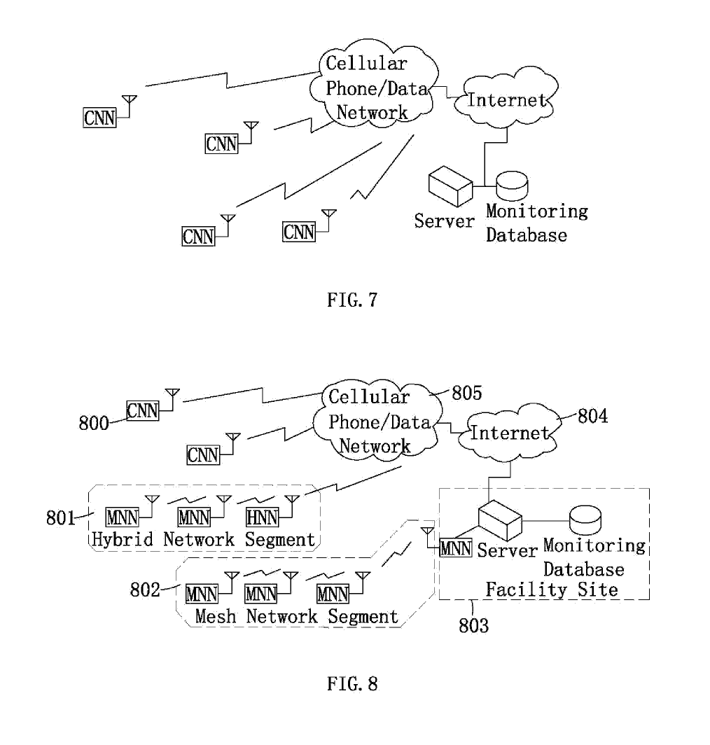

FIG. 7 is a schematic diagram of a cellular GPRS/CDMA network only topology, where CNN represents a cellular network/data node, through which the data can be sent as a short message service (SMS) message to a remote cellular device (Cellular Phone) via a mobile network carrier. An internet server (Server) can also preferably be accessed for storing the monitoring data in a monitoring database. This kind of server can either be a conventional one or can be run in the Cloud. The data could alternatively or additionally be delivered to the internet and further to a PC screen via the TCP/IP protocol stack built-in on the GPRS/CDMA modules. The advantage of a cellular network is that there is no limitation with respect to the distance between the monitoring network nodes. A disadvantage to the cellular network is provider service fees required to obtain and maintain the cellular network coverage.

FIG. 8 is an overall schematic diagram of independent and hybrid network topologies illustrating independent mesh-network and cellular network systems s utilized in separate enclosures 800 and 802, as well as a hybrid network system combined in a single enclosure 801. The optimal network configuration can be selected and utilized based on the environmental situation and cost considerations. It should be recognized that only a mesh-network requires a terminal Node nearby the server.

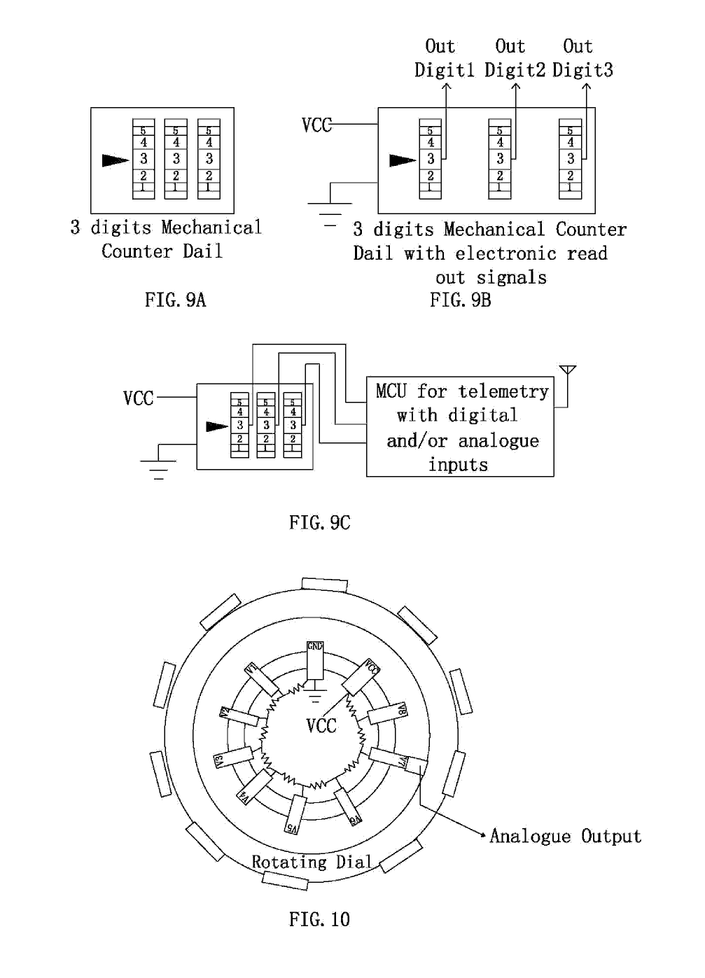

FIG. 9A is a schematic diagram illustrating a conventional 3-digit mechanical counter dial, and FIG. 9B illustrates a modification thereto to produce a 3-digit electronic readout signal. FIG. 9C is a schematic diagram illustrating a mechanical counter telemetry system for providing a remote readout from the modified mechanical counter of FIG. 9B. Referring to FIG. 9C, in this embodiment, a wireless network telemetry system is indicated. However, the telemetry system can additionally or alternatively interface with a wired network, a PLC network, or any other communications network.

FIG. 10 is a schematic diagram of a mechanical counter modified to produce an analog readout corresponding to the counter position. Referring to FIG. 10, the analog readout dial can be configured to simply to add the 10 voltage levels of the analog output corresponding to the 10 possible positions of each digit of the decimal dials. An analog readout requires less signal wires between the counter dial and the MCU interface than a digital readout, as it requires only one analog signal per digit. For each signal, however, it further requires an ADC to convert the analog signal to digital data for transmission. The ten voltage levels of the analog output correspond to the ten possible positions of the decimal dial.

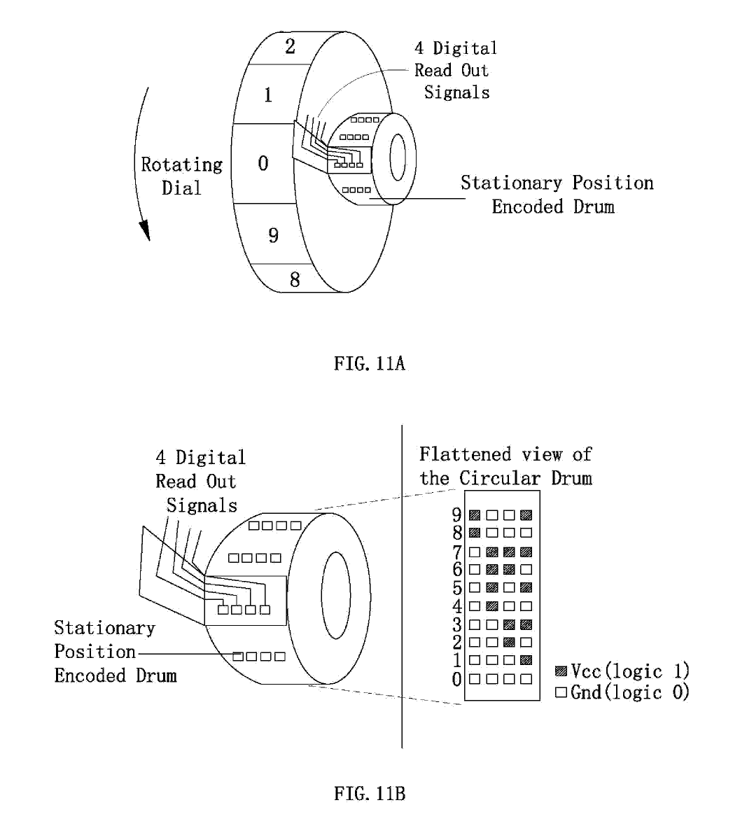

FIGS. 11A and 11B are schematic diagrams illustrating a mechanical counter modified to produce a digital readout corresponding to the counter position. Referring to FIGS. 11A and 11B, the digital readout dial is shown in FIG. 11A, wherein a rotating dial 1110 is attached to a sweeping detector head 1115 and a stationary drum 1120 is provided with electrical contact points that are either connected to Vcc (logic 1) or Ground (logic 0). As the dial turns to a different position, the 4 contact points on the sweeping head will move to another position and make contacts with another set of 4 contact points on the stationary drum.

The stationary drum with encoded logic 0 and logic 1 contacting pins is shown in further detail in FIG. 11B. The sweeping head will sweep through the 10 positions as the rotating dial moves and make contact with each of the 4 contacting points on the drum at a time. With the contacting points connected to Vcc and Gnd as shown, a unique 4-bit value is produced for every position of the dial. The corresponding signals will be output through the 4 digital readout signals. The digital read out system requires more signal wires between the counter dial and the MCU interface as it requires 4 digital GPIO signals per digit. It does not, however, require an ADC for its operation since it produces a digital signal directly.

In summary, according to principles of the present inventive concepts, an innovative communication network can be utilized between a MOV surge arrester monitor node and a central control center in a substation or above level in a national power grid system. The surge arrester monitor node preferably senses the total leakage current level through the surge arrester and transmits a signal corresponding to the sensed leakage current through the communications network.

The communications network can include a wireless network such as a mesh network or a public communication network (such as a cellular GSM/GPRS or CDMA network protocol), or both. These wireless network systems can be used independently or combined to remotely monitor the arrester conditions in a real-time or a quasi-real time manner. In addition, or alternatively, a power line communication (PLC) network could be used to transmit signals from the surge arrester monitor node to the control center, or between various relay nodes in the system.

A wireless communications system can be formed using ZigBee specifications and IEEE 802.15.4 compliant apparatuses or other individual RF protocols, such as SNAP, or using a cellular GPRS/CDMA network, either independently or in combination. In one embodiment, the wireless communications system comprises a CEL (California Eastern Lab) ZIC2410 module that consists of an RF transceiver with baseband modem, a hardwired MAC and an embedded 8051 microcontroller with internal flash memory. Although CEL provides its customers with the CEL ZigBee software stack in a compiled library, an embodiment can implement the SNAP network operating system that is the protocol spoken by all Synapse Wireless devices. The SNAP system may be preferable as it includes not only all the features of a ZigBee compliant system, but also provides other advantages, including no need for Coordinators, as well as easy to write scripts to monitor input signals (analog or digital) and control outputs.

A PLC protocol may be desirable, however, in cases where the MOVs are installed in a switching cabinet that distributes the electric power to an industrial or residential community. In such circumstances, a metal case containing the MOV arrester circuitry may block signal transmissions of a regular wireless RF transceiver.

Innovative circuitry to acquire the total leakage current of the MOV arrester at its ground terminal is also provided. More particularly, one or more opto-couplers, i.e., opto-coupler configurations, can be implemented for intercepting the leakage current signal in the primary stage, relaying the leakage current signal to the secondary stage, and triggering the 10 pins of a radio module to transmit a corresponding signal through air. One advantage of this configuration is that it provides isolation of the radio electronics that may otherwise be vulnerable to high current surges from the MOV arrester circuit, since the MOV arrester circuit provides the grounding path for high current surges.

As shown in FIG. 1, to limit the currents in alternative directions, two current limiting resistors can be inserted in series but on separate sides of the primary terminals of the opto-coupler (OC) which is formed by bi-directional LED diodes that can conduct bi-directionally under AC voltages. A biasing resistor can be connected in shunt with the opto-coupler primary circuit to provide the bias that the OC requires for conduction and to set up the pre-determined leakage current threshold.

A mini-type zinc-oxide varistor (ZOV) can be connected in shunt with the biasing resistor and opto-coupler primary branch to provide surge protection. The mini ZOV is preferably selected to be able to withstand an 8/20 us surge current up to 100 kA or above. This design is assumed to be able to cover a full service scope for all levels of high voltage power lines up to 220 kV or above.

The output of the OC can be set up as a linear mode output, a digital mode output, or both. The linear mode output can be connected to a sensor ADC input of a radio module to monitor the analog signal of the leakage current in real time. A digital mode output configuration can send a logic signal out that triggers the GPIO pins of a connected radio module when the leakage current increases to a pre-defined level, indicative of an initial deteriorating condition of the arrester. The digital mode output can thereby wake up the interrupt GPIO pins and transmit the state change to remote peers of the mesh network system and through the mesh network to the central control center of the system and upper levels of the network hierarchy.

The output of the opto-coupler can further be connected to at least one display or sound producing apparatus such as colored LEDs or an audible alarm that is configured to output a visible or audible warning signal.

In a mesh network system, the mesh network can comprise one or more full-time awake monitor nodes, referred to as Router nodes or Routers, and Sleeper nodes or Sleepers that wake-up based on predetermined events. The Router Nodes can be powered up, for instance, by a small power solar panel, and are ready to receive and transmit its own or other nodes' signals any time. The Sleeper Nodes, however, can be powered by solar power or by disposable or rechargeable batteries, depending on their power consumption level, and can be set up in a wakeup-on-event mode in order to conserve power. In an alternative configuration, the Sleep nodes can be set up in a wakeup-on-timer mechanism. For instance, a synchronicity timer can be set up for the network nodes to waking-up the nodes and time the signal transmissions. The ratio between the number of Routers and Sleepers may depend on the module transmitting power and broadcasting range (which could range, for example, from 100 ft to 3000 ft in line of sight). Since the Routers normally consume much more power than the Sleepers, a higher Sleeper to Router ratio means more power savings, and thus a more cost effective system.

When the radio module is set in a power-down mode, all the clocks of the MCU are preferably stopped and current consumption is minimized. Upon receiving an interrupt signal, which is provided for wake-up, the radio module exits the power-down mode. In addition to, or instead of, external interruption, at least one sleep timer can be provided in the radio module to cause it to exit from the power-down mode.

Where an external interrupt drives the wake-up, there should be at least one fault that has occurred to drive the logic state change. In this case, the RF transceiver starts to broadcast a message and continues to broadcast it until the event ends or that will broadcast in a programmed mode that sends out messages at predefined time intervals. In a sleep timer wake-up case, if a predetermined sleep time is reached, the system will wake up at the predetermined time, and a programmed state flow will direct the system to check the states of each of the opto-couplers' outputs, i.e., the states of the relevant GPIOs' inputs of the radio module. If no faults are detected, the program will order the system back to sleep. If faults are detected, however, it will broadcast a fault message across the communications network.

The RF transceiver can also be programmed to routinely broadcast a message that reports a message such as “Hello, I am OK”, or the like on a regular time bases.

Each of the Router nodes are responsible for listening for and intercepting signals from the connected nodes and for forwarding the intercepted signals from awoken Sleepers through nearby Router nodes all the way back to the central control center and above levels of the network hierarchy.

As illustrated in FIG. 2, each Router node or Sleeper node may be responsible for monitoring every phase of power in an arrester of a 3-phase power line. The arrester circuit can include three units, each unit installed at a ground wire of the MOV arrester for a corresponding phase. The phases can be separated from one another by a distance based on the IEC or local power grid standards. In this embodiment, although leakage current detectors can be provided for each of the MOV arresters, only a central case includes a radio module and a current sensing PCB, which are both preferably enclosed in the central case. The other two cases may be configured to enclose only a current sensing PCB that is connected to the central case via signal and power wires and water-proof connecters.

In circumstances where the availability of a field power supply has been a major concern, the system may be powered, for instance, by either an externally installed solar panel or a mini wind turbine system. Alternatively, the system may be powered by a line voltage if installed in a switch cabinet where an 110V line voltage is available. For instance, in some embodiments, the system may be installed in a switch cabinet having an 110V mains jack available, and a Power Line Communication (PLC) protocol may be used for signal transmission through the mains lines.

Another potential power source can be a Capacitive Voltage Transformer (CVT) which is commonly installed at high voltage substations or on some field transmission line towers. The CVT can be used to output a non-regulated 100-200V AC voltage through a secondary winding of a transformer in which the primary winding is connected to the capacitor voltage divider. The availability of this power supply source is determined by the individual facility and depends on the regulations. In some embodiments, a CVT may be available in the electrical power transmission line, and its terminal can be used for a carrier communication purpose. In such systems, it is possible that the signal can be transmitted using Power Line Communication (PLC) protocols.

In embodiments where a predetermined leakage current threshold is in the same range as current consumption of the radio transceiver, it may be possible to make use of a solid-state relay (SSR) device to provide the system power. For instance, primary terminals may be connected in series in the ground line of the arrester to provide charging power for one or more rechargeable batteries through a charge controller to supply the power for the entire system. In this case, the entire system would be in a power-off state until a fault occurs that causes the leakage current to increase to a predetermined threshold. After a short time, the leakage current would provide sufficient power to power-up the system and cause the leakage current detector to detect the excessive leakage current and trigger the radio transceiver to send out the appropriate warning signal.

In a still further embodiment, an induction coil arrangement, such as a Rogowski coil arrangement, may be able to collect lightning energy from a strike and have it stored in an energy bank, such as a capacitor bank. For instance, if the Rogowski coil is installed in a way such that it is surrounding the MOV ground terminal wire and can collect the flux of a lightning induced magnetic field, the lightning energy may then be processed through a rectifier and filter circuitry and used to power the leakage current sensing unit and the radio module in a delayed mode. In other words, the transient magnetic field may generate an EMI current in the coil that can charge a capacitor bank to a level that can be used as a power supply for the said monitoring system.

In yet another embodiment, a coil having a toroidal core may be able to collect energy from the alternatively changed electromagnetic field induced by a 60 Hz AC high voltage power line and convert it into an electrical current of up to tens of mAs with a few volts of output. In some designs, this can be used as a power supply for the system.

In some embodiments, rather than using an entirely metal case to enclose the sensing and radio transmission circuits, a top portion of the case may be made of a plastic or other material that will not shield or block the radio signal transmission from a radio module equipped with a PCB antenna. If an external antenna is used, however, a metal outer case could be utilized and may be useful for shielding circuitry from an external EM field.

In preferred embodiments, a bottom plate of the case is made of a conducting metal and connected to the Earth ground. One way of connecting the high voltage terminal of the monitor to the MOV arrester's ground wire is through a screw bolt that is insulated from the ground plate by a ceramic or rubber sheath insulating ring.

Besides Router nodes and Sleeper nodes, a Terminal node may also be provided in the control center for intercepting the broadcasting signals and transmitting them to a connected PC or other computing device through a USB jack. The signals can be processed, for example, via an embedded programmable firmware.

A programmable firmware may also be configured to upload the required scripts to each Router node or Sleeper node or Terminal node via a USB connector or directly through the air.

A script program can be configured to write data embedded in the signal to a text file which records the date/time of the remote node events based on the PC clock, node Mac addresses and the real-time states of the remote nodes. The program can be further configured to issue a condition report on a regular basis at pre-defined intervals. In the case where the signals provide a large amount of data flow, a database file and a server may be utilized.

A user interface (UI) can be used to display the logged data in the text file on a PC or other computing device, such as smart phone, or through other display terminals via other network infrastructures such as Ethernet or 3G/4G. The UI can be configured to implement as many user friendly features as possible, such as table (tree) model view, sort/filter proxy model, MAC address mapping to user friendly node names, a Google map marked with the nodes locations, or other features so that users can sort and filter the logged data by the date/time or time period, nodes name, or status of the nodes and easily identify the fault locations.

A database server can also be installed and serve as a database center. This server can be connected to different broadband information networks such as the internet through devices such as E10 or other serial connection modes. All the desired users can then be enabled to access the data remotely via broadband network infrastructures such as Ethernet or 3G/4G using a PC, smart phone, or other stationary or mobile computing devices.

A hybrid network can be used to transmit the signals. For instance, the hybrid network can include a mesh-network and a cellular network operating together in a combined way. The Router Node can be arranged in the mesh-network and collect data from the Sleeper Nodes at up or downstream locations along the mesh network. The Router Node can further be configured to perform functions similar to a Terminal Node and can be serially connected to a GSM/GPRS module, and communicate via AT command. The GSM/GPRS module can then, for instance, send a short message service (SMS) message through a mobile carrier's service to a smart phone and/or can access the internet and deliver the data to a PC screen through the TCP/IP stack built-in on the cellular module.

The hybrid network can be set up as a group of separate and independent segments. In each segment, a Router Node can be used to perform as a Terminal Node by collecting data from the nearby Sleep Nodes, while the GPRS module operates as a substation, handshaking with the Router Node through serial connections and conveying the data to remote receivers such as smart phones via SMS or by accessing the internet and delivering the data to a PC via a TCP/IP stack built-in on the GPRS module. Each of the segments can be configured to maximize their capability to carry as many as Sleep Nodes as possible to reduce the costs of paying the GPRS network service fees.

The choice of whether or not to implement a mesh network only, a cellular network only, or a hybrid network topology may depend on the environmental demands as well as cost considerations. In general, because a mesh network topology does not rely on a cellular network, it therefore does not have the same coverage limitations or network related service fees. A cellular network, on the other hand, has no radio range restriction between the monitoring nodes and the control center, but does require regular payment of a service fee. When the number of nodes becomes large, the accumulated service fees associated with a cellular network can become considerable.

According to additional principles of the present inventive concepts, a complementary way of monitoring the MOV conditions and sending them out for remote readout is provided. According to these principles, as with the earlier embodiments, the system registers the time and counts of a surge strike and sends them out via the communications network for a remote readout. In this embodiment, however, these features can be realized by renovating existing off-the-shelf mechanical counters to produce either an analog or a digital readout mechanism, or both, as illustrated in FIGS. 10 and 11.

As shown in FIG. 10, the conventional dial is simply modified to produce 10 voltage levels of analog output corresponding to the 10 positions of the decimal dial. Analog readout requires less signal wires between the counter dial and the MCU interface as it requires only one analog signal per digit. For each signal, however, it requires an ADC to convert the analog signal to digital data for transmission. A digital read out, however, requires more signal wires between the counter dial and the MCU interface as it requires 4 digital GPIO signals per digit. It does not, however, require ADC for its operation.

Having described and illustrated principles of the present invention in various preferred embodiments thereof, it should be apparent that the invention can be modified in arrangement and detail without departing from such principles.

What is claimed is:

1. A power grid surge arrester monitoring system comprising:
a surge arrester monitor node comprising a current sensor for sensing a leakage current level in a surge arrester in the power grid, said surge arrester monitor node configured to produce a signal corresponding to the sensed leakage current;
a central control center located at a substation or above level in a power grid system; and
a network communication device arranged in communication with the surge arrester monitor node and configured to transmit the signal from the surge arrester monitor node to the central control center via a network.

2. The power grid surge arrester monitoring system according to claim 1, wherein the network comprises a wireless network comprising either or both of:
a mesh network; and
a public communication network,
wherein the mesh network and the public communication network can be independently utilized or utilized together in a hybrid combination wherein the mesh network is responsible for collecting data while the public communication network is responsible for transmitting data, to remotely monitor the arrester conditions in a real-time or a quasi-real time manner, and wherein the mesh network communicates with the public communication network through a serial connection.

3. The power grid surge arrester monitoring system of claim 2, wherein the mesh network comprises a ZigBee compliant or SNAP network.

4. The power grid surge arrester monitoring system of claim 2, wherein the public communications network comprises a cellular GSM/GPRS or CDMA network.

5. The power grid surge arrester monitoring system of claim 1, wherein the network comprises a power line communication (PLC) network.

6. The system of claim 5, wherein the surge arrester comprises a metal-oxide varistor (MOV) arrester installed in a switching cabinet having a metal case that distributes electric power to an industrial or residential community.

7. A metal-oxide varistor (MOV) surge arrester monitoring system comprising:
circuitry configured to acquire a total leakage current of a MOV arrester at its ground terminal;
a wireless communications module configured to wirelessly transmit a signal; and
one or more opto-couplers arranged to intercept a leakage current signal corresponding to the total leakage current in the primary stage, relay the signal to the secondary stage, and transmit the leakage current signal to the wireless communications module which can then wirelessly transmit the leakage current signal to an external monitoring station.

8. The system of claim 7, further comprising isolation circuitry configured to electrically isolate the wireless communications module from high current surges passing through the MOV arrester circuit to prevent damage to the wireless communications module.

9. The system of claim 8, wherein the isolation circuitry comprises two current limiting resistors inserted in series on separate sides of the primary terminals of the opto-coupler, said opto-coupler being formed using bi-directional LED diodes that can conduct bi-directionally under AC voltages to limit currents in alternate directions.

10. The system of claim 9, wherein a biasing resistor is further connected in shunt with a primary circuit of the opto-coupler to provide a bias required by the opto-coupler for conduction and to establish a pre-determined leakage current threshold.

11. The system of claim 10, wherein a mini-type ZOV (zinc-oxide varistor) is connected in shunt with the biasing resistor and an opto-coupler primary branch to provide surge protection.

12. The system of claim 11, wherein the mini ZOV is selected to be able to withstand an 8/20 us surge current up to 100 kA or above.

13. The system of claim 7, wherein an output of the opto-coupler is set up in a linear mode, a digital mode, or both.

14. The system of claim 13, wherein the output of the opto-coupler is set up in linear mode, and wherein the linear mode output is connected to a sensor ADC input of a radio module to monitor an analog signal of the leakage current in real time.

15. The system of claim 13, wherein the output of the opto-coupler is configured in a digital mode, and wherein the digital mode configuration is arranged to send a logic signal out that triggers GPIO pins of the wireless communications module when the leakage current increases to a pre-defined level to wake up the interrupt GPIO pins of the wireless communications module and wirelessly transmit a state change of the MOV surge arrester, and wherein said pre-defined level is selected to indicate an initial deteriorating condition of the MOV surge arrester.

16. A surge arrester monitoring system comprising:
circuitry configured to monitor a state of a surge arrester; and
a wireless communications module configured to wirelessly transmit a signal corresponding to a state change of the surge arrester via a wireless network.

17. The system of claim 16, wherein the wireless network is a mesh network, and wherein the state change is transmitted to remote peers of the wireless network system and through the remote peers to a central control center of the system.

18. The system of claim 17, wherein the mesh network comprises one or more always awake router nodes and one or more sleeper nodes configured to wakeup based on one or more predetermined events or preset time intervals.

19. The system of claim 18, wherein each node is responsible for monitoring every phase of arresters of 3-phase power lines, assembled in 3 units and installed at the ground wire of a MOV arrester of each phase

20. The system of claim 19, further comprising a central case enclosing both a radio module and a current sensing unit in a single enclosure, and two secondary cases in which only a current sensing unit is enclosed, said secondary cases being connected to the central case via signal and power wires and waterproof connectors.
